(19) United States
(12) Patent Application Publication
(10) Pub. No.: US 2023/0411140 A1
(43) Pub. Date: Dec. 21, 2023

(54) METHOD FOR PRODUCING A SUBSTRATE FOR EPITAXIAL GROWTH OF A GALLIUM-BASED III-N ALLOY LAYER

(71) Applicant: Soitec, Bernin (FR)

(72) Inventor: Eric Guiot, Bernin (FR)

(21) Appl. No.: 18/248,169

(22) PCT Filed: Oct. 4, 2021
(86) PCT No.: PCT/FR2021/051709

§ 371 Date: Apr. 6, 2023

(30) Foreign Application Priority Data
Oct. 6, 2020 (FR) FR2010206

(51) Int. Cl. H01L 21/02; H01L 29/66; C30B 31/22; C30B 29/36; C30B 29/40; C30B 25/18

(52) U.S. Cl. CPC H01L 21/02002; H01L 29/66462; H01L 21/0254; H01L 21/02378; C30B 31/22; C30B 29/36; C30B 29/406; C30B 25/186

(57) ABSTRACT

A method of producing a substrate for epitaxial growth of a gallium-based III-N alloy layer comprises the following consecutive steps: —providing a donor substrate of semi-insulating monocrystalline silicon carbide, —implanting ionic species in the donor substrate so as to form a zone of weakness defining a thin layer of semi-insulating monocrystalline SiC to be transferred, —bonding the donor substrate to a first receiving substrate by means of a bonding layer, —detaching the donor substrate along the zone of weakness so as to transfer the thin layer of semi-insulating monocrystalline SiC on to the first receiving substrate, —forming an additional layer of semi-insulating SiC on the transferred thin layer, —bonding the additional layer to a second receiving substrate having a high electrical resistivity, —removing at least a portion of the bonding layer so as to detach the first receiving substrate and expose the layer of transferred semi-insulating monocrystalline SiC.

### CROSS-REFERENCE TO RELATED APPLICATIONS

This application is a national phase entry under 35 U.S.C. § 371 of International Patent Application PCT/FR2021/051709, filed Oct. 4, 2021, designating the United States of America and published as International Patent Publication WO 2022/074318 A1 on Apr. 14, 2022, which claims the benefit under Article 8 of the Patent Cooperation Treaty to French Patent Application Serial No. FR2010206, filed Oct. 6, 2020.

### TECHNICAL FIELD

The present disclosure relates to a process for fabricating a substrate for the epitaxial growth of a layer of gallium nitride, to a process for fabricating such a layer of gallium nitride and to a process for fabricating a high-electron-mobility transistor (HEMT) in such a layer of gallium nitride.

### BACKGROUND

III-N semiconductors, in particular, gallium nitride (GaN), aluminum gallium nitride (AlGaN) or indium gallium nitride (InGaN), appear to be particularly promising, in particular, as regards the formation of high-power light-emitting diodes (LEDs) and of electronic devices operating at high frequency, such as high-electron-mobility transistors (HEMTs) or other field-effect transistors (FETs).

In so far as these III-N alloys are difficult to find in the form of bulk substrates of large size, they are generally formed by heteroepitaxy, i.e., by epitaxy on a substrate made of a different material.

Selection of such a substrate, in particular, takes into account the difference in lattice parameter and the difference in coefficient of thermal expansion between the material of the substrate and the III-N alloy. Specifically, the larger these differences, the greater the risk of formation, in the layer of III-N alloy, of crystal defects, such as dislocations, and the greater the risk of generation of high mechanical stresses, liable to cause excessive strains.

The materials most frequently considered for the heteroepitaxy of III-N alloys are sapphire and silicon carbide (SiC).

Apart from its smaller difference in lattice parameter with gallium nitride, silicon carbide is particularly preferred for high-power electronic applications because of its thermal conductivity, which is clearly higher than that of sapphire, and which, therefore, allows the thermal energy generated during component operation to be more easily dissipated.

In radiofrequency (RF) applications, it is sought to use semi-insulating silicon carbide, i.e., silicon carbide that typically has an electrical resistivity higher than or equal to 10⁵ Ω·cm, in order to minimize parasitic losses (generally called “RF losses”) in the substrate. However, this material is particularly expensive and currently is available only in the form of substrates of limited size.

Silicon would allow fabricating costs to be drastically decreased and substrates of large size to be accessed, but structures of III-N-alloy-on-silicon type are penalized by RF losses and by a poor dissipation of heat.

Composite structures, such as SopSiC or SiCopSiC structures, have also been investigated [1] but have not proved to be entirely satisfactory. These structures comprise a layer of single-crystal silicon or a layer of single-crystal SiC (intended to form a seed layer for the epitaxial growth of the gallium nitride) on a polycrystalline SiC substrate, respectively. Although polycrystalline SiC is a material that is inexpensive, that is available in the form of substrates of large size and that dissipates heat well, these composite structures are penalized by the presence of a layer of silicon oxide at the interface between the layer of single-crystal silicon or SiC and the polycrystalline SiC substrate, which forms a thermal barrier hindering the dissipation of heat from the layer of III-N alloy to the polycrystalline SiC substrate.

### BRIEF SUMMARY

One aim of the present disclosure is, therefore, to remedy the aforementioned drawbacks and, in particular, limitations related to the size and cost of semi-insulating SiC substrates.

The aim of the disclosure is, therefore, to provide a process for fabricating a substrate for the epitaxial growth of a III-N alloy based on gallium, in particular, with a view to forming HEMTs or other high-frequency, high-power electronic devices in which RF losses are minimized and the dissipation of heat is maximized.

To this end, the disclosure provides a process for fabricating a substrate for epitaxial growth of a layer of gallium nitride (GaN), of aluminum gallium nitride (AlGaN) or of indium gallium nitride (InGaN), comprising the following successive steps:
providing a single-crystal semi-insulating silicon-carbide donor substrate,
implanting ionic species into the donor substrate so as to form a weakened region that defines a thin layer of single-crystal semi-insulating SiC to be transferred,
bonding the donor substrate to a first receiver substrate via a bonding layer,
detaching the donor substrate along the weakened region so as to transfer the thin layer of single-crystal semi-insulating SiC to the first receiver substrate,
forming an additional layer of semi-insulating SiC on the transferred thin layer of semi-insulating SiC,
bonding the additional layer of semi-insulating SiC to a second receiver substrate having a high electrical resistivity,
removing at least one portion of the bonding layer so as to detach the first receiver substrate and uncover the transferred layer of single-crystal semi-insulating SiC.

By “high-frequency,” what is meant in the present text is a frequency higher than 3 kHz.

By “high-power,” what is meant in the present text is a power density higher than 0.5 W/mm injected through the gate of the transistor.

By “high electrical resistivity,” what is meant in the present text is an electrical resistivity higher than or equal to 100 Ω·cm.

By “semi-insulating SiC,” what is meant in the present text is silicon carbide having an electrical resistivity higher than or equal to 10⁵ Ω·cm.

This process allows a low-cost substrate to be formed, based on silicon, diamond or ceramic, having a high electrical resistivity and a high thermal conductivity, available in large size, comprising a layer of semi-insulating SiC allowing the final structure to benefit from the good properties thereof as regards the dissipation of heat and the limitation of RF losses. Since the layer of semi-insulating SiC makes direct contact with the receiver substrate, the structure further contains no thermal barrier.

A process that consisted in forming the layer of semi-insulating SiC by epitaxy directly on a silicon substrate of high electrical resistivity would lead to the formation of a high number of dislocations in the semi-insulating SiC because of the difference in lattice parameter between silicon and silicon carbide. In contrast, the process according to the disclosure makes it possible to use, as seed for the subsequent growth of the III-N alloy based on gallium, a layer of single-crystal semi-insulating SiC the quality of which is optimal because it was obtained via transfer from the donor substrate. The remainder of the layer of semi-insulating SiC, namely the additional layer deposited on the transferred layer, which is located on the side of the transferred layer opposite the layer of III-N alloy, is not necessarily single-crystal.

The use of the first receiver substrate, which plays the role of temporary carrier, allows the silicon face of the semi-insulating SiC to be oriented optimally in the various steps of the process.

The use of the first receiver substrate, which plays the role of temporary carrier, allows the silicon face of the semi-insulating SiC to be oriented optimally in the various steps of the process.

According to advantageous but optional features of the process, which may be implemented separately or in any technically possible combination thereof:
the first receiver substrate and the donor substrate have a difference in coefficient of thermal expansion smaller than or equal to 3×10⁻⁶ K⁻¹;
the first receiver substrate is an SiC substrate having a crystal quality lower than that of the donor substrate;
the thickness of the thin layer of single-crystal semi-insulating SiC transferred to the first receiver substrate has a thickness smaller than 1 μm;
the bonding layer is formed from a material that remains thermally stable during the formation of the layer of semi-insulating SiC and that is able to be removed from the interface between the transferred layer of single-crystal semi-insulating SiC and the first receiver substrate;
the bonding layer is a layer of silicon nitride or of gallium nitride;
removing at least one portion of the bonding layer comprises a chemical etch, a delamination by laser and/or the application of a mechanical stress;
the additional layer of semi-insulating SiC is formed by simultaneously depositing silicon, carbon and vanadium;
the second receiver substrate is a silicon substrate having an electrical resistivity higher than or equal to 100 Ω·cm;
the additional layer of semi-insulating SiC has a thickness between 1 and 5 μm;
the second receiver substrate is a polycrystalline SiC substrate, a diamond substrate or a polycrystalline MN substrate;
the additional layer of semi-insulating SiC has a thickness smaller than or equal to 80 μm;
the ionic species are implanted through the silicon face of the donor substrate, and the silicon face of the donor substrate is bonded to the first receiver substrate, so that, after the bonding layer has been removed, the silicon face of the transferred layer of single-crystal semi-insulating SiC is uncovered;
the process further comprises a step of recycling the segment of the donor substrate detached from the transferred layer, with a view to forming a new donor substrate.

Another subject of the disclosure relates to a process for fabricating a layer of III-N alloy based on gallium on a substrate obtained using the process that has just been described.

The process comprises:
providing a substrate fabricated using the process such as described above,
performing epitaxial growth of the layer of gallium nitride on the silicon face of the transferred layer of single-crystal semi-insulating SiC of the substrate.

The layer of gallium nitride typically has a thickness between 1 and 2 μm.

Another subject of the disclosure relates to a process for fabricating a high-electron-mobility transistor (HEMT) in such a layer of III-N alloy.

The process comprises:
fabricating by epitaxy a layer of gallium nitride using the process such as described above,
forming a heterojunction by epitaxy of a layer of a III-N material different from gallium nitride on the layer of gallium nitride,
forming a channel of the transistor level with the heterojunction,
forming a source, a drain and a gate of the transistor on the channel.

### BRIEF DESCRIPTION OF THE DRAWINGS

Further features and advantages of the disclosure will become apparent from the following detailed description, with reference to the appended drawings, in which:

FIG. 1 is a schematic cross-sectional view of a single-crystal semi-insulating SiC donor substrate;

FIG. 2 is a schematic cross-sectional view of the donor substrate of FIG. 1, in which substrate a weakened region has been formed by implanting ionic species in order to define a thin layer to be transferred;

FIG. 3 is a schematic cross-sectional view of a temporary carrier covered with a removable bonding layer;

FIG. 4 is a schematic cross-sectional view of the temporary carrier of FIG. 3 being joined to the donor substrate of FIG. 2 via the removable bonding layer;

FIG. 5 is a schematic cross-sectional view of the donor substrate being detached along the weakened region in order to transfer the thin layer of single-crystal semi-insulating SiC to the temporary carrier;

FIG. 6 is a schematic cross-sectional view of the thin layer of single-crystal SiC transferred to the temporary carrier after its free surface has been polished;

FIG. 7 is a schematic cross-sectional view of an additional layer of semi-insulating SiC being formed on the transferred thin layer of single-crystal semi-insulating SiC;

FIG. 8 is a schematic cross-sectional view of the structure of FIG. 7 being joined to a receiver substrate via the additional layer of semi-insulating SiC;

FIG. 9 is a schematic cross-sectional view of the removal of the temporary carrier from the structure of FIG. 8 by chemical etching of the removable bonding layer so as to uncover the silicon face of the transferred layer of semi-insulating SiC;

FIG. 10 is a schematic cross-sectional view of a layer of GaN being formed by epitaxy on the silicon face of the transferred layer of semi-insulating SiC;

FIG. 11 is a schematic cross-sectional view of a heterojunction being formed by epitaxy of a layer of a III-N alloy different from GaN on the layer of GaN.

For the sake of legibility of the figures, the various layers have not necessarily been shown to scale.

### DETAILED DESCRIPTION

The disclosure provides a process for fabricating substrates for the epitaxial growth of binary or ternary III-N alloys based on gallium. The alloys comprise gallium nitride (GaN), aluminum gallium nitride (AlₓGa₁₋ₓN, where 0<x<1, designated in abbreviated form by AlGaN below) and indium gallium nitride (InₓGa₁₋ₓN, where 0<x<1, designated in abbreviated form by InGaN below). For the sake of conciseness, in the rest of the text the fabrication of a substrate for the epitaxial growth of a layer of GaN will be described; however, a person skilled in the art will be able to tailor the growth conditions to form a layer of AlGaN or of InGaN, the substrate serving for this epitaxial growth remaining the same.

The process uses a donor substrate of single-crystal semi-insulating silicon carbide (SiC), a thin layer of which, transferred using the SMART CUT® process to a first receiver substrate, will serve as seed for the growth of an additional layer of semi-insulating SiC, which is not necessarily single-crystal. As will be seen below, the additional layer of semi-insulating SiC will allow the final structure to be provided with a sufficiently large thickness of semi-insulating SiC to substantially reduce the RF losses at an optimized cost insofar as only the segment of the layer intended for the growth of the layer of GaN is single-crystal.

To this end, a single-crystal semi-insulating SiC donor substrate having an excellent crystal quality, i.e., in particular, a substrate free of dislocations, will be chosen.

In certain embodiments, the donor substrate may be a bulk substrate of single-crystal semi-insulating SiC. In other embodiments, the donor substrate may be a composite substrate, comprising a superficial layer of single-crystal semi-insulating SiC and at least one other layer of another material. In this case, the layer of single-crystal semi-insulating SiC will have a thickness larger than or equal to 0.5 μm.

There are various crystal forms (also called polytypes) of silicon carbide. The most common are the forms 4H, 6H and 3C. Preferably, the single-crystal semi-insulating silicon carbide is chosen from the 4H and 6H polytypes, but any polytype may be used to implement the present disclosure.

In the figures, a donor substrate 10 of single-crystal semi-insulating SiC has been shown.

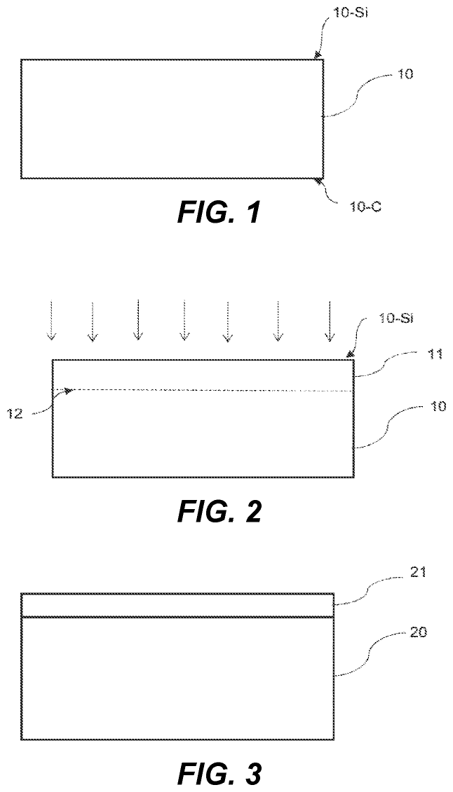

As known per se, as illustrated in FIG. 1, such a substrate has a silicon face 10-Si and a carbon face 10-C.

At the present time, processes of epitaxy of GaN are mainly implemented on the silicon face of the semi-insulating SiC. However, it is not impossible to grow GaN on the carbon face of the semi-insulating SiC. The orientation of the donor substrate (silicon face/carbon face) during the implementation of the method is chosen depending on the face of the semi-insulating SiC intended for the growth of the layer of GaN.

With reference to FIG. 2, ionic species are implanted into the donor substrate 10, so as to form a weakened region 12 that defines a thin layer 11 of single-crystal semi-insulating SiC. The implanted species typically comprise hydrogen and/or helium. A person skilled in the art will be able to define the required implantation dose and energy.

When the donor substrate is a composite substrate, the implantation is carried out into the surface layer of single-crystal semi-insulating SiC of the substrate.

Preferably, the ionic species are implanted through the silicon face 10-Si of the donor substrate. As will be seen below, this orientation of the donor substrate makes it possible to put, at the surface of the final substrate intended for the growth of the layer of GaN, the silicon face of the semi-insulating SiC, which is more favorable. However, if it is envisioned to grow the layer of GaN on the carbon face of the semi-insulating SiC, the ionic species must be implanted through the carbon face 10-C of the donor substrate.

Preferably, the thin layer 11 of single-crystal semi-insulating SiC has a thickness smaller than 1 μm. Specifically, such a thickness is accessible on an industrial scale with the SMART CUT® process. In particular, the implantation tools available on industrial fabrication lines allow such an implantation depth to be obtained.

With reference to FIG. 3, a first receiver substrate 20 is moreover provided.

The main function of the first receiver substrate is to temporarily hold the thin layer 11 of single-crystal semi-insulating SiC between its transfer from the donor substrate and the growth of the additional layer of semi-insulating SiC on the layer of single-crystal semi-insulating SiC.

To this end, the first receiver substrate is chosen to have a coefficient of thermal expansion substantially equal to that of the semi-insulating SiC, in order not to generate stresses or strains during the formation of the additional layer of semi-insulating SiC. Thus, particularly advantageously, the first receiver substrate and the donor substrate (or the layer of single-crystal semi-insulating SiC in the case of a composite donor substrate) have a difference in coefficient of thermal expansion smaller than or equal to 3×10⁻⁶ K⁻¹ as absolute value.

Preferably, the first receiver substrate is also made of SiC so as to minimize the difference in coefficient of thermal expansion. Particularly advantageously, the first receiver substrate 20 is an SiC substrate having a crystal quality lower than that of the donor substrate. What is meant by that is that the first receiver substrate may be a polycrystalline SiC substrate, or indeed a substrate of single-crystal SiC but that may comprise dislocations of all types (contrary to the single-crystal semi-insulating SiC of the donor substrate that is chosen for an excellent crystal quality in order to ensure the quality of the epitaxial layer of GaN). Such a substrate of lower crystal quality has the advantage of being less expensive than a substrate of same quality as the donor substrate, while being perfectly adapted to the function of temporary carrier.

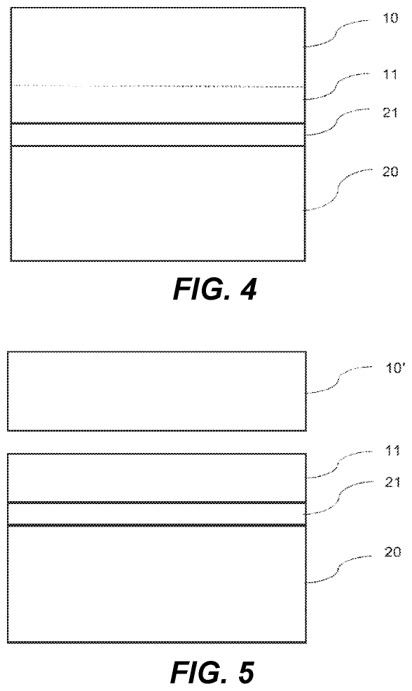

With reference to FIG. 4, the donor substrate 10 comprising the thin layer 11 of single-crystal SiC is bonded to the first receiver substrate 20.

To ensure a good adhesion of the donor substrate to the first donor substrate, a bonding layer 21 is formed at the interface between the substrates.

In FIG. 3, the bonding layer 21 is formed on the first receiver substrate 20, but, in other embodiments that are not illustrated, the bonding layer may be formed on the donor substrate (on the side of the thin layer 11), or indeed partially on the donor substrate and partially on the first receiver substrate.

The bonding layer is formed from a material that remains thermally stable during the subsequent formation of the additional layer of semi-insulating SiC on the thin layer 11.

By way of indication, since epitaxy of 4H- or 6H-SiC is carried out at a temperature typically higher than 1500° C., the material of the chosen bonding layer will not degrade or disassociate at such a temperature if the additional layer of semi-insulating SiC is formed by epitaxy. However, insofar as an excellent crystal quality is not required for the additional layer of semi-insulating SiC, it is not essential to use an epitaxy process. A faster deposition process at a lower temperature, leading to an additional layer that is polycrystalline or comprises dislocations, may therefore be used, which allows the duration and cost of fabricating the substrate to be reduced.

Moreover, the material of the bonding layer is able to be removed from the interface between the transferred layer of single-crystal semi-insulating SiC and the first receiver substrate 20, for example, by means of a selective etch, which is optionally assisted by a plasma.

According to one preferred embodiment, the bonding layer is a layer of silicon nitride or of gallium nitride. The thickness of the layer is typically between 10 nm and a few hundred nanometers.

With reference to FIG. 5, the donor substrate is detached along the weakened region 12. In a way known per se, the detachment may be caused by a heat treatment, a mechanical action, or a combination of these means.

The effect of this detachment is to transfer the thin layer 11 of single-crystal semi-insulating SiC to the first receiver substrate 20. The remainder 10′ of the donor substrate may optionally be recycled with a view to another use.

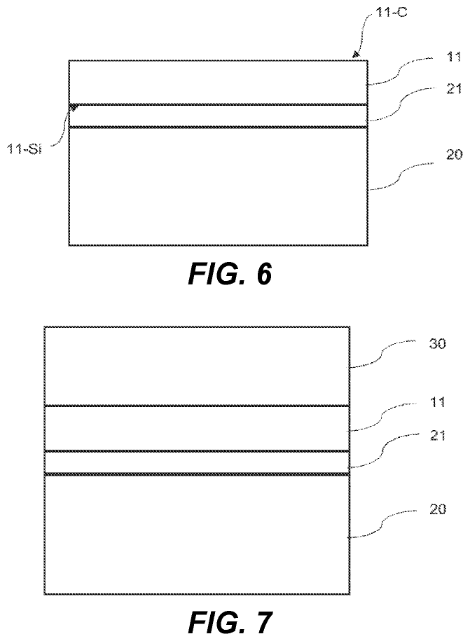

As illustrated in FIG. 6, the free face of the transferred thin layer 11 of single-crystal semi-insulating SiC is the carbon face 11-C (the silicon face 11-Si being on the side of the bonding interface). This face is polished, for example, by chemical-mechanical polishing (CMP), to remove defects related to the implantation of ionic species and to decrease the roughness of the thin layer 11.

With reference to FIG. 7, an additional layer 30 of semi-insulating SiC is formed on the thin layer 11 of single-crystal semi-insulating SiC. The polytype of the SiC of the additional layer is advantageously identical to that of the transferred layer.

As indicated above, the additional layer 13 is not necessarily single-crystal but may be polycrystalline, which allows deposition to be carried out at a lower temperature than an epitaxy. In any case, on account of the small difference in coefficient of thermal expansion between the material of the first receiver substrate and the SiC, the mechanical stresses generated in the stack are minimized.

There are various techniques for forming semi-insulating SiC. According to one embodiment, the layer of SiC is doped with vanadium during its epitaxial growth. According to another embodiment, silicon, carbon and vanadium are simultaneously deposited using suitable precursors in an epitaxial reactor.

The additional layer of semi-insulating SiC advantageously has a thickness larger than 1 μm, so as to contribute in a significant way to the dissipation of heat within the final structure. This thickness is larger than the thickness directly accessible with the SMART CUT® process using industrially available equipment. In addition, this additional layer may be formed by a less costly process than the transferred layer of the donor substrate.

Thus, the process consisting in transferring a layer of single-crystal semi-insulating SiC with a thickness smaller than 1 μm, then in forming a layer of semi-insulating SiC, which is not necessarily single-crystal by epitaxy on the transferred layer, allows the technical limits of the implantation tools that are industrially available to carry out the SMART CUT® process to be circumvented and the cost of the fabricating process to be reduced.

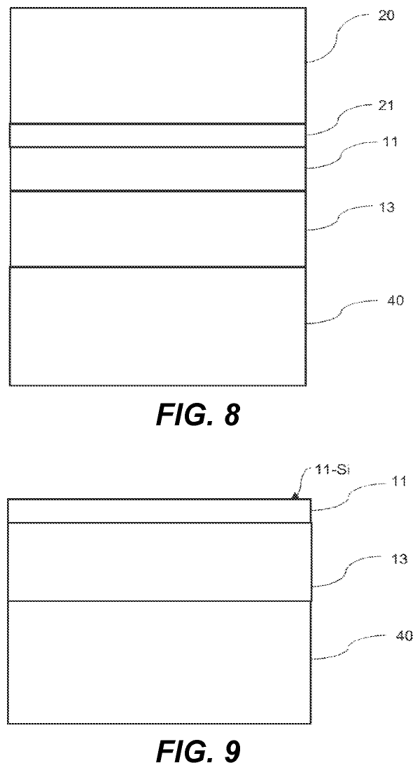

With reference to FIG. 8, a second receiver substrate 40, which has a high electrical resistivity, is provided, and bonded to the additional layer 13 of semi-insulating SiC. For example, the second receiver substrate may be a silicon substrate having an electrical resistivity higher than or equal to 100 Sam, or, preferably, a polycrystalline SiC substrate, a polycrystalline AlN substrate or a diamond substrate.

The thickness of the additional layer 13 of semi-insulating SiC will possibly be chosen depending on the material of the second receiver substrate. Thus, when the second receiver substrate is a silicon substrate of high electrical resistivity, the additional layer 13 of semi-insulating SiC will advantageously have a thickness between 1 and 5 μm. When the second receiver substrate is made of polycrystalline AlN, diamond or polycrystalline SiC, it will possibly be advantageous for the additional layer 13 of semi-insulating SiC to have a much larger thickness, possibly up to 80 μm, for example, about 50 to 80 μm, to improve the dissipation of heat within the final structure.

Next, at least some of the bonding layer 21 is removed so as to detach the first receiver substrate from the rest of the structure. During this removal, the bonding layer 21 must be sufficiently damaged to allow a dissociation from the structure. Any suitable means may be employed. For example, but non-limitingly, the bonding layer may be removed via a chemical etch, a delamination by laser and/or the application of a mechanical stress.

As illustrated in FIG. 9, there therefore remains, at the end of this separation, a structure that consists in succession of the second receiver substrate 40, of the additional layer 13 of semi-insulating SiC and of the transferred thin layer 11 of single-crystal semi-insulating SiC. Any residues of the bonding layer 21 are removed by polishing and/or etching.

The uncovered face of the transferred layer 11 is the silicon face of the single-crystal semi-insulating SiC, which is favorable to the epitaxial growth of GaN. A substrate suitable for epitaxial growth of III-N alloys has thus been formed.

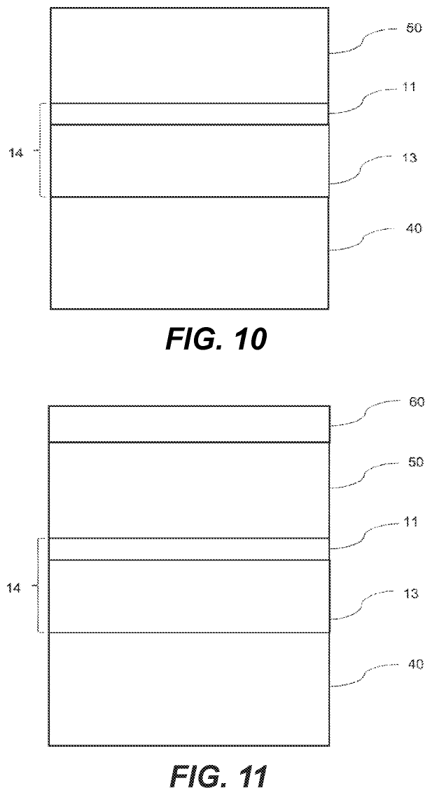

With reference to FIG. 10, a layer 50 of GaN (or, as mentioned above, of AlGaN or InGaN) is grown on the free face of the layer 11 of semi-insulating SiC. The thickness of the layer 50 is typically between 1 and 2 μm.

Next, as illustrated in FIG. 11, a heterojunction is formed by growing, by epitaxy, on the layer 50, a layer 60 of a III-N alloy different from that of the layer 50.

It is thus possible to continue the fabrication of transistors, in particular, of HEMTs, from this heterojunction, using processes known to those skilled in the art, the channel of the transistor being formed level with the heterojunction, and the source, the drain and the gate of the transistor being formed on the channel.

The structure thus obtained is particularly advantageous in that it comprises a relatively thick layer of semi-insulating SiC, of which only a portion serving as seed for the epitaxial growth of the layer of III-N alloy has to be single-crystal, and that both dissipates heat well and limits RF losses. Moreover, the second receiver substrate, which bears the layer of semi-insulating SiC, makes direct contact with the layer, so that the structure does not comprise any thermal barrier.

Thus, a HEMT or another high-frequency, high-power electronic device, formed in a layer of II-N alloy formed by epitaxy on such a structure, has minimized RF losses and a maximized dissipation of heat.

### REFERENCES

[1] Comparative study on stress in AlGaN/GaN HEMT structures grown on 6H-SiC, Si and on composite substrates of the 6H-SiC/poly-SiC and Si/poly-SiC, M. Guziewicz et al., Journal of Physics: Conference Series 100 (2008) 040235.

1. A method of fabricating a substrate for epitaxial growth of a layer of gallium nitride (GaN), of aluminum gallium nitride (AlGaN) or of indium gallium nitride (InGaN), comprising the following successive steps:
providing a single-crystal semi-insulating silicon-carbide donor substrate;
implanting ionic species into the donor substrate so as to form a weakened region defining a thin layer of single-crystal semi-insulating SiC to be transferred;
bonding the donor substrate to a first receiver substrate via a bonding layer;
detaching the donor substrate along the weakened region so as to transfer the thin layer of single-crystal semi-insulating SiC to the first receiver substrate;
forming an additional layer of semi-insulating SiC on the transferred thin layer of semi-insulating SiC;
bonding the additional layer of semi-insulating SiC to a second receiver substrate having a high electrical resistivity; and
removing at least one portion of the bonding layer so as to detach the first receiver substrate and uncover the transferred thin layer of single-crystal semi-insulating SiC.

2. The method of claim 1, wherein the first receiver substrate and the donor substrate have a difference in coefficient of thermal expansion smaller than or equal to 3×10⁻⁶ K⁻¹.

3. The method of claim 1, wherein the first receiver substrate is an SiC substrate having a crystal quality lower than that of the donor substrate.

4. The method of claim 1, wherein a thickness of the transferred thin layer of single-crystal semi-insulating SiC transferred to the first receiver substrate is smaller than 1 μm.

5. The method of claim 1, wherein the bonding layer is formed from a material that remains thermally stable during formation of the additional layer of semi-insulating SiC and that is capable of being removed from an interface between the transferred thin layer of single-crystal semi-insulating SiC and the first receiver substrate.

6. The method of claim 1, wherein the bonding layer is a layer of silicon nitride or gallium nitride.

7. The method of claim 1, wherein removing the at least one portion of the bonding layer comprises a chemical etch, a delamination by laser and/or application of a mechanical stress.

8. The method of claim 1, wherein the additional layer of semi-insulating SiC is formed by simultaneously depositing silicon, carbon and vanadium.

9. The method of claim 1, wherein the second receiver substrate is a silicon substrate having an electrical resistivity higher than or equal to 100 Ω·cm.

10. The method of claim 9, wherein the additional layer of semi-insulating SiC has a thickness between 1 and 5 μm.

11. The method of claim 1, wherein the second receiver substrate is a polycrystalline SiC substrate, a diamond substrate or a polycrystalline AlN substrate.

12. The method of claim 11, wherein the additional layer of semi-insulating SiC has a thickness smaller than or equal to 80 μm.

13. The method of claim 1, wherein:
the ionic species are implanted through a silicon face of the donor substrate; and
the silicon face of the donor substrate is bonded to the first receiver substrate;
so that, after the bonding layer has been removed, the silicon face of the transferred thin layer of single-crystal semi-insulating SiC is uncovered.

14. The method of claim 1, further comprising a step of recycling a segment of the donor substrate detached from the transferred thin layer.

15. A method of fabricating by epitaxy a layer of gallium nitride, comprising:
providing a substrate fabricated using the process according to claim 1; and
performing epitaxial growth of the layer of gallium nitride on a silicon face of the transferred thin layer of single-crystal semi-insulating SiC of the substrate.

16. The method of claim 15, wherein the layer of gallium nitride has a thickness between 1 and 2 μm.

17. A method of fabricating a high-electron-mobility transistor (HEMT), comprising:
fabricating by epitaxy a layer of gallium nitride using the process according to claim 17;
forming a heterojunction by epitaxy of a layer of a III-N material different from gallium nitride on the layer of gallium nitride;
forming a channel of the transistor level with the heterojunction; and
forming a source, a drain and a gate of the transistor on the channel.

18. The method of claim 2, wherein the first receiver substrate is an SiC substrate having a crystal quality lower than that of the donor substrate.

19. The method of claim 18, wherein a thickness of the transferred thin layer of single-crystal semi-insulating SiC transferred to the first receiver substrate is smaller than 1 μm.

20. The method of claim 19, wherein the bonding layer is formed from a material that remains thermally stable during formation of the additional layer of semi-insulating SiC and that is capable of being removed from an interface between the transferred thin layer of single-crystal semi-insulating SiC and the first receiver substrate.
